(19) United States
(12) Patent Application Publication
(10) Pub. No.: US 2026/0128740 A1
(43) Pub. Date: May 7, 2026

(54) GATE DRIVER SYSTEMS AND RELATED METHODS

(71) Applicant: SEMICONDUCTOR COMPONENTS INDUSTRIES, LLC, Scottsdale, AZ (US)

(72) Inventors: Vijay B. RENTALA, Plano, TX (US); Steven GRAY, Jacksonville, FL (US); Scott ALLEN, Apex, NC (US)

(73) Assignee: SEMICONDUCTOR COMPONENTS INDUSTRIES, LLC, Scottsdale, AZ (US)

(21) Appl. No.: 19/376,781

(22) Filed: Oct. 31, 2025

Related U.S. Application Data
(60) Provisional application No. 63/715,484, filed on Nov. 1, 2024.

(51) Int. Cl. H03K 17/687; G06N 3/092

(52) U.S. Cl. CPC H03K 17/6871; G06N 3/092

(57) ABSTRACT

Implementations of a system configured for operation of a field effect transistor may include a gate driver coupled with a memory and a microcontroller unit and a plurality of analog to digital converters, the gate driver configured to be coupled with a gate of a field effect transistor where the gate driver may be configured to generate a drive signal with at least two levels for the gate of the field effect transistor. The drive signal with at least two levels may be generated using a deep reinforcement learning agent and data associated with one or more parameters of the field effect transistor.

### CROSS REFERENCE TO RELATED APPLICATIONS

This document claims the benefit of the filing date of U.S. Provisional Patent Application 63/715,484, entitled “Gate Driver Systems and Related Methods” to Vijay B. Rentala which was filed on Nov. 1, 2024, the disclosure of which is hereby incorporated entirely herein by reference.

### BACKGROUND

### 1. Technical Field

Aspects of this document relate generally to semiconductor devices used to control gates of various other semiconductor devices. Particular implementations also include gate driver systems for silicon carbide semiconductor devices.

### 2. Background

Various semiconductor devices have been devised that work by controlling flow of electricity. A wide variety of systems that include such semiconductor devices have been developed to allow integration of semiconductor devices with electrical equipment. Control systems utilize these semiconductor devices as part of a process of directing the operation of the electrical equipment.

### SUMMARY

Implementations of a system configured for operation of a field effect transistor may include a gate driver coupled with a memory and a microcontroller unit and a plurality of analog to digital converters, the gate driver configured to be coupled with a gate of a field effect transistor where the gate driver may be configured to generate a drive signal with at least two levels for the gate of the field effect transistor. The drive signal with at least two levels may be generated using a deep reinforcement learning agent and data associated with one or more parameters of the field effect transistor.

Implementations of a system configured for operation of a field effect transistor may include one, all, or any of the following:

The gate driver may be configured to be coupled with a telecommunication network and the telecommunication network may be configured to be operatively coupled with a cloud computing system which may include the deep reinforcement learning agent. The cloud computing system may use the deep reinforcement learning agent and the data associated with the one or more parameters of the field effect transistor to train the deep reinforcement learning agent and then transmit the deep reinforcement learning agent across the telecommunication network to the gate driver for storing in the memory.

The deep reinforcement learning agent may be included in the memory and the gate driver may be configured to use the deep reinforcement learning agent and the data associated with one or more parameters of the field effect transistor to generate the drive signal.

The deep reinforcement learning agent may be included in the memory and may be configured to communicate with a cloud computing system over a telecommunication network coupled with the gate driver where the cloud computing system may be configured to use the data associated with one or more parameters of the field effect transistor to train the deep reinforcement learning agent to generate the drive signal with at least two levels associated with an operating area for the field effect transistor.

The deep reinforcement learning agent may be one of a deep Q-network, a double deep Q-network, an Actor-Critic agent, a policy gradient agent, a Monte Carlo tree search agent, an imitation learning agent, or any combination thereof.

The deep reinforcement learning agent may be trained using a deep neural network and a Markov decision process.

Implementations of a system configured for operation of a field effect transistor may include a first gate driver and a second gate driver, the first gate driver and the second gate driver each coupled with a memory and a corresponding plurality of analog to digital converters. The first gate driver may be configured to be coupled with a gate of a first field effect transistor and the second gate driver configured to be coupled with a gate of a second field effect transistor where the first gate driver may be configured to generate a first drive signal with at least two levels for the gate of the first field effect transistor. The first drive signal with at least two levels may be generated using a first deep reinforcement learning agent and data associated with one or more parameters of the first field effect transistor. The second gate driver may be configured to generate a second drive signal with at least two levels for the gate of the second field effect transistor where the second drive signal with at least two levels generated using a second deep reinforcement learning agent and data associated with one or more parameters of the second field effect transistor.

Implementations of a system configured for operation of a field effect transistor may include one, all, or any of the following:

The first deep reinforcement learning agent and the second deep reinforcement learning agent may be the same deep reinforcement learning agent.

Each of the first gate driver and the second gate driver may be configured to be coupled with a telecommunication network and the telecommunication network may be configured to be operatively coupled with a cloud computing system which may include the first deep reinforcement learning agent and second deep reinforcement agent. The cloud computing system may use the first deep reinforcement learning agent and the data associated with the one or more parameters of the first field effect transistor to train the first deep reinforcement learning agent and then transmits the first deep reinforcement learning agent across the telecommunication network to the first gate driver for storing in the memory. The cloud computing system may use the second deep reinforcement learning agent and the data associated with the one or more parameters of the second field effect transistor to train the second deep reinforcement learning agent and then transmit the second deep reinforcement learning agent across the telecommunication network to the second gate driver for storing in the memory.

The first deep reinforcement learning agent may be included in the memory and the first gate driver may be configured to use the first deep reinforcement learning agent and the data associated with one or more parameters of the first field effect transistor to generate the first drive signal. The second deep reinforcement learning agent may be included in the memory and the second gate driver may be configured to use the second deep reinforcement learning agent and the data associated with one or more parameters of the second field effect transistor to generate the second drive signal.

The first deep reinforcement learning agent may be included in the memory and may be configured to communicate with a cloud computing system over a telecommunication network coupled with the first gate driver where the cloud computing system may be configured to use the data associated with one or more parameters of the first field effect transistor to train the first deep reinforcement agent to generate the first drive signal with at least two levels associated with an operating area for the first field effect transistor. The second deep reinforcement learning agent may be included in the memory and may be configured to communicate with a cloud computing system over a telecommunication network coupled with the second gate driver where the cloud computing system may be configured to use the data associated with one or more parameters of the second field effect transistor to train the second deep reinforcement agent to generate the second drive signal with at least two levels associated with an operating area for the second field effect transistor.

The first deep reinforcement learning agent or the second deep reinforcement learning agent may be one of a deep Q-network, a double deep Q-network, an Actor-Critic agent, a policy gradient agent, a Monte Carlo tree search agent, an imitation learning agent, or any combination thereof.

The first deep reinforcement learning agent or second deep reinforcement agent may be trained using a deep neural network and a Markov decision process.

Implementations of a method of training a deep reinforcement learning agent used during operation of a field effect transistor may include providing a gate driver coupled with a memory, a microcontroller unit, and a plurality of analog to digital converters, the gate driver coupled with a gate of a field effect transistor. The method may include transmitting data from the plurality of analog to digital converters associated with one or more parameters of the field effect transistor to a cloud computing system and, using the data, training a deep reinforcement learning agent. The method may include transmitting the deep reinforcement learning agent to the memory; and, using the deep reinforcement learning agent, generating a drive signal with at least two levels for the gate of the field effect transistor.

Implementations of a method of training a deep reinforcement learning agent may include one, all or any of the following:

Training the deep reinforcement learning agent may include training at least partially on the gate driver itself using the microcontroller unit.

Training the deep reinforcement learning agent may include training only with the cloud computing system.

Training the deep reinforcement learning agent may include training only on the gate driver itself using the microcontroller unit.

The deep reinforcement learning agent may be one of a deep Q-network, a double deep Q-network, an Actor-Critic agent, a policy gradient agent, a Monte Carlo tree search agent, an imitation learning agent, or any combination thereof.

Training the deep reinforcement learning agent further may include training using a deep neural network and a Markov decision process.

Training the deep reinforcement learning agent further may include where training defines an operating area for the field effect transistor.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a schematic of an implementation of a traction inverter that includes six silicon carbide metal oxide field effect transistors (MOSFETs) therein;

FIG. 2 is a schematic of an implementation of a gate driver;

FIG. 3 is a block diagram of the circled region of FIG. 2 illustrating an implementation of an artificial intelligence agent; and

FIG. 4 is a flow chart of a method of training a deep reinforcement learning agent.

### DESCRIPTION

This disclosure, its aspects and implementations, are not limited to the specific components, assembly procedures or method elements disclosed herein. Many additional components, assembly procedures and/or method elements known in the art consistent with the intended gate driver systems and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such gate driver systems and related methods, and implementing components and methods, consistent with the intended operation and methods.

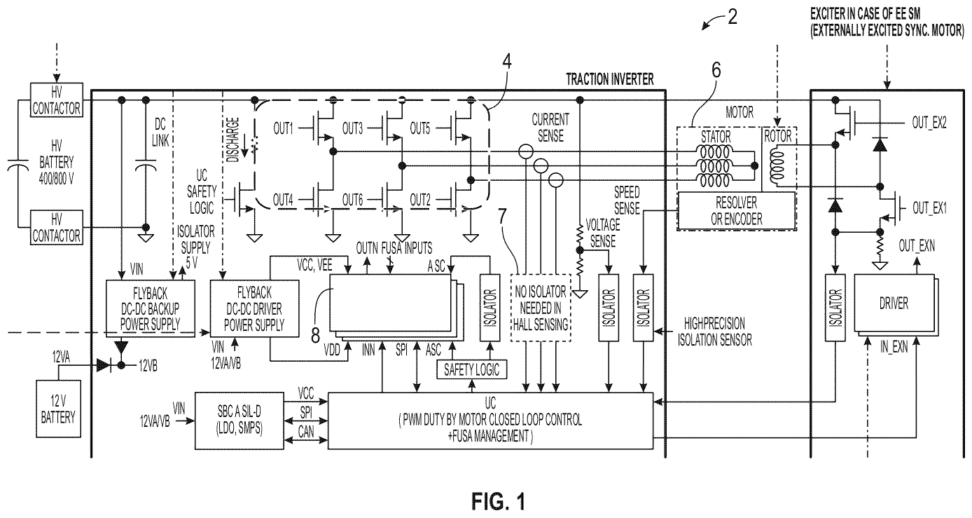

Referring to FIG. 1, a schematic diagram of an implementation of a portion of a traction inverter 2 is illustrated. In this particular traction inverter design, six silicon carbide transistors 4 are included coupled, two coupled to each phase of a stator of a motor 6 indicated in the dotted region in FIG. 1. In this implementation, the motor 6 may be a permanent magnet synchronous motor (PMSM) or an externally excited synchronous motor (EESM). The operation of the silicon carbide transistors 4 is controlled using a corresponding gate driver 8 paired with each silicon carbide transistor 4 and operatively coupled with a gate of each transistor. The gate drivers 8 in various implementations utilize pulse width modulation to control the flow of current through each silicon carbide transistor 4 and thus the current passing through each phase of the stator of the motor 6. The resulting time varying current results in a corresponding time varying magnetic field generated by the stator that then exerts a corresponding force on the rotor of the motor 6 causing the rotor to turn with a varying number of revolutions per minute to accelerate or decelerate (or maintain rotations at a fixed number of revolutions per minute). In this implementation, a current sense block 7 is used to sense the current from the silicon carbide transistors 4 to provide the current data to the gate drivers 8. The gate drivers 8 utilize the current data from the current sense block 7 to determine whether overcurrent or short circuit conditions are present to ensure the drivers can shut down the silicon carbide transistors to prevent damage to them. In this implementations, Hall sensing is used in the current sense block 7 to provide the current data to the gate drivers 8.

One of the challenges of operating with silicon carbide transistors and other semiconductor devices that operating using a significant amount of power is that a fault condition can rapidly destroy the devices if an intervention by a controller like a gate driver is not carried out in time. Because of the binary nature of operation of the typical controller which is only assessing either a dangerous condition (short circuit/overcurrent, etc.) exists at a given time or not, the silicon carbide transistors 4 are designed and manufactured to handle greater than 50% excess load capacity over their nominal operating rating. This excess load capacity means the device could endure a short circuit or overcurrent condition long enough until detected by the driver and the device is shut down.

However, the binary nature of operating using the gate drivers who are only evaluating whether a dangerous condition exists and then, if none is present, operating the silicon carbide transistors 4 at a fixed specified operating point means that significant device capacity remains unused. The various device and method implementations disclosed herein include gate drivers that are able to evaluate and learn the actual operating ability of the silicon carbide transistor they are operating (or another semiconductor device type they control). In this way, the gate drivers are able to proactively prevent dangerous conditions from occurring and/or improve the performance of the silicon carbide transistors and/or allow for full utilization of the silicon carbide transistor's actual load capacity in an application.

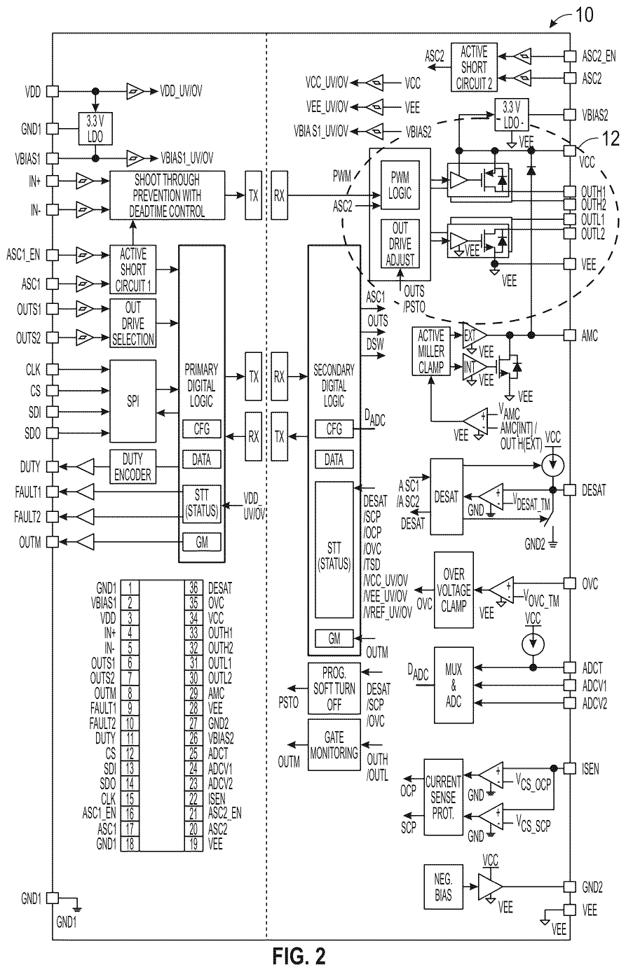

Referring to FIG. 2, a schematic diagram and pinout of an exemplary implementation of a gate driver 10 is illustrated. In FIG. 2, the portion 12 of the gate driver 10 that generates the output signal(s) used to drive the gate is included in the circle which operates under direction of the MCU(s) in the gate driver 10. In various system and method implementations disclosed herein, the use of an artificial intelligence model/system is employed to assist with and/or create/generate the output signals(s) used to drive the gate of the corresponding silicon carbide transistor. In this way, the gate driver 10 now can do more than just operate the silicon carbide transistor in a fixed manner, monitor it for failure, and/or shut it down if a fault condition is detected. The gate driver may also perform the functions of the current sense block 7 in FIG. 1, allowing that component to be removed from the circuit entirely as will be discussed herein. The ability to push the silicon carbide transistor to a higher performance condition while still being in the safe operating area (SOA) for that silicon carbide transistor when increased system performance is needed (or conversely dropping performance when lower system performance is needed) would be advantageous and improve the overall functioning of any system in which the driver/silicon carbide transistor is included. The challenge with various gate driver designs is that they lack the ability to do optimization with the actual performance characteristics of a specific silicon carbide transistor to which the gate driver is electrically connected and/or any optimization with a known set of empirically measured set of parameters of the specific type of silicon carbide transistors to which the gate driver is connected.

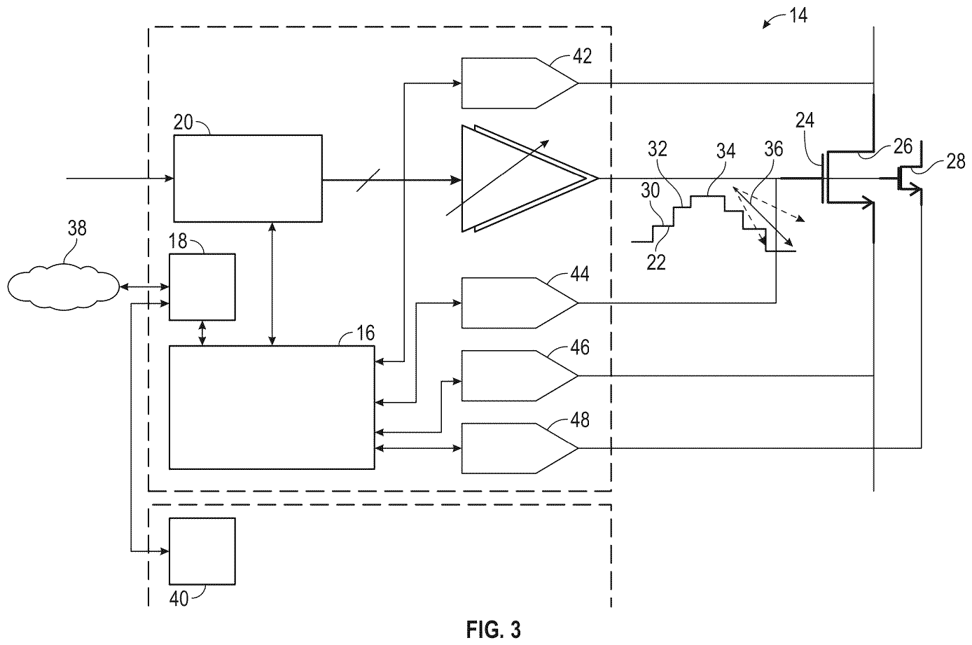

Referring to FIG. 3, a block diagram of an implementation of an artificial intelligence agent 14 including various component implementations added to the portion 2 of the gate driver indicated in FIG. 2 is illustrated. In this implementation, to allow for data collection and/or optimized operation, real-time monitoring of specific terminals or all terminals of the gate driver 10 and/or corresponding silicon carbide transistor (FET) may be carried out (gate, drain, source, currents, etc.). In the implementation illustrated in FIG. 3, high speed multibit analog to digital converters (ADCs) are utilized to collect the operating data from the silicon carbide FET 26 and from a sensing FET 28 coupled to the gate 24 of the silicon carbide FET 26. ADC 42 is used to measure the incoming source current to the silicon carbide FET 26 and supply real time data to either a dedicated microcontroller unit (MCU) or an existing MCU 16 is used to process the data in the memory. ADC 44 is used to measure the gate voltage of gate 24 of the silicon carbide FET 26 and supply real time gate voltage data to the MCU 16. ADC 46 is used to measure the drain voltage from the silicon carbide FET 26 in real time and provide the voltage data to the MCU 16. ADC 48 is used to measure the drain voltage from sensing FET 28 and supply that drain voltage to provide additional information regarding the gate voltage and operation of the silicon carbide FET 26. Since all of this data is provided at high speed and accuracy due to the operating speed of the ADCs 42, 44, 26, 48, the need to have a separate current sense block 7 included in a circuit in which the silicon carbide FET 26 is installed is no longer needed. The gate driver has now taken over this function. Furthermoe, with all of this real time data available to the MCU during operation from all key points of the silicon carbide FET 26, the MCU is able to now able to assess how the silicon carbide FET 26 is performing in response to changes in load or changes in operating conditions supplied by the gate driver. This additional data permits the use of artificial intelligence modeling and the use of artificial intelligence models to be implemented as the primary control systems for the silicon carbide FET 26.

As illustrated, a neural network (NN) model/system 18 is operatively coupled with the MCU and the associated memory. In some implementations, the neural network system 18 may be stored/implemented as machine readable instructions in the memory. In various implementations, this neural network system may include, by non-limiting example, a deep neural network, a recurrent neural network, a convolutional neural network, a long short-term memory network, any combination thereof, or any other deep neural network type. While the use of a neural network system 18 is illustrated in FIG. 3, other types of artificial intelligence models may be employed including, by non-limiting example, a deep reinforcement learning agent, all of which are collectively referred to herein as a “neural network” regardless of whether they employ a neural network exclusively, partially, or utilize another system of creating artificial intelligence.

Where a deep reinforcement learning agent is employed in the neural network system 18, various types may be employed including, by non-limiting example, a deep Q-network, a double deep Q-network, an Actor-Critic agent, a policy gradient agent, a Monte Carlo tree search agent, an imitation learning agent, any combination thereof, or any other type of deep reinforcement learning model. In other implementations, generative artificial intelligence models may be employed. In various method implementations, where a deep reinforcement learning agent/model is employed in the neural network 18, the deep reinforcement learning agent may be trained/generated using a deep neural network and a Markov decision process in a particular implementation of a method of training a deep reinforcement agent as discussed in this document.

The neural network system 18 assists the MCU 16 with determining signals to be sent to the pulse width modulation (PWM) generation module 20, an implementation of which is illustrated in the portion 12 in FIG. 2. The PWM generation module 20 then uses the signals to create a drive signal 22 for the gate 24 of the silicon carbide FET 26. A sensing (SENSE) silicon carbide FET 28 is used to monitor the gate voltage and provide remote sensing data collection to the MCU 16 as illustrated in FIG. 3. As illustrated in FIG. 3, the result of the input of the neural network system 18 to the MCU 16 is to create a programmed drive signal 22 that has various levels 30, 32, 34 (three in this case) that create a drive signal 22 with a programmable slope 36 (as indicated by the adjoining dotted alternate slope lines). The ability to generate a programmed drive signal 22 with various levels and resulting slope allows the gate driver 10 to optimize the operation of the silicon carbide FET 26 rather than just operate it at a single preset level or several preset levels that do not or are not optimally correlated with the desired/possible performance of the silicon carbide FET 26. It also allows the gate driver 10 to change the rate of change of the slope of the drive signal 22 which gives the gate driver 10 more transient operating control over the silicon carbide FET 26. The ability to send the programmed drive signal 22 can allow the gate driver 10 to learn (via the neural network system 18) over time how to generate an optimal drive signal for the silicon carbide FET 26 to achieve one or more specific desired outputs from the FET 26. This ability may allow the silicon carbide FET 26 to be operated in a higher performance portion of its SOA than a “one size fits all approach” of using a single or multiple preset drive signal levels. The ability to create a programmed drive signal 22 also allows the gate driver to respond rapidly to detected changes in operating conditions of the silicon carbide FET 26 to avert damage from a short circuit condition, an overcurrent condition, or another condition that could damages the silicon carbide FET. Finally, the ability to generate a drive signal 22 with a programmed slope 36 may allow the gate driver 10 (via the neural network system 18) to learn how to change the performance of the silicon carbide FET 26 in an optimal way from high to low performance or to increase the speed at which it reaches a high performance or low performance level, or how to operate the silicon carbide FET 26 in an energy efficient, high performance, higher risk, lower risk, and/or balanced operating scheme. Finally, the neural network system 18 may assist with fault/reliability fault detection of the silicon carbide FET 26 as changes in the FET that signal upcoming or imminent failure can be detected using the neural network system 18. This ability to have real time or near real time response to fault conditions may allow the 50% load excess requirement for the silicon carbide FET used to provide safety margin to be eliminated. This would allow the silicon carbide FET to be operated in a system at or near its actual rate capacity without the use of load excess to provide safety margin. This also means that the additional cost involved in using an overdesigned device for a given load application can be avoided. In the artificial intelligence agent 14 implementation of FIG. 3, the neural network system 18 implements a deep reinforcement learning agent training using data from the silicon carbide FET 26.

The ability to include the MCU, neural network/artificial intelligence, analog components and high voltage components on the same semiconductor chip is enabled by the use of appropriate process technology. In some implementations, multiple semiconductor die in a stacked configuration may be utilized for the various functional and system components. This mixture of digital, analog, and artificial intelligence enabling components in the same semiconductor package is unique.

The neural network model may be trained and implemented in the artificial intelligence agent 14 using a wide variety of method implementations. In some implementations, training data is collected from the operation of a wide number of similar gate drivers connected to similar silicon carbide FETs over a wide variety of operating states within the SOA and the neural network is trained with this training data. In other implementations, a first principles model is used to generate hypothetical training data for use in training the neural network system 18 which then enters a learning phase after the gate driver 10 is coupled to the specific silicon carbide FET 26 where the neural network system 18 observes terminal data and then experiments/learns over time how to find and operate the silicon carbide FET 26 in optimized areas in the SOA of the silicon carbide FET 26. In yet other implementations, the neural network system 18 can be left untrained and placed in an observational data collection and training mode until the MCU 16 or other component determines that the neural network system 18 is able to provide adequate instructions and is able to meet minimum drive signal requirements, at which point the neural network system 18 is given direct control and continues to learn and train. In yet other implementations, the neural network system 18 is installed in an untrained state and immediately begins to provide drive signal inputs subject to override by an ordinary process control system(s) implemented in the PWM generation module 20 and/or the MCU 16 (proportional, integral, and/or derivative control system, for example). In this implementation, the neural network system 18 is free to learn and experiment while the ordinary process control system prevents operation in areas that are beyond the SOA. Over time as data is collected, the competency of the neural network system 18 increases and the need for the ordinary process control system to intervene decreases.

In yet other method and system implementations, the neural network system 18 may be periodically refreshed/updated using a telecommunication network using an external data input from a centralized computing resource 38 (like a cloud-based resource) that actually trains the model included in the system. The centralized computing resource may, in some method implementations, regularly or continuously collect data from one or more gate drivers during operation for use as training data or may rely on historical or simulated data to perform the training. The neural network system 18 may be refreshed on a regular basis or on an as-needed basis by the centralized computing resource when sub-optimal performance is detected. In implementations where a centralized computing resource 38 is used to train/generate models, the need for the on-board computing power to do the training activity on the gate driver itself may be reduced/eliminated. In some implementations, since multiple gate drivers are involved in the same unit like the traction inverter disclosed herein, the centralized computing system 38 and/or the gate drivers in the unit may pool their data and/or computing capacity to perform neural network system training/calculations and then implement the shared results. As illustrated in FIG. 3, more than one neural network system may be employed in the same gate driver and in some implementations, different neural network systems using the same or different models 40 may be used for different desired performance levels for separate or the same silicon carbide FETs. For example, one neural network system with a first model may be employed to maintain a high performance level while another neural network system with a different model may be employed to maintain a low performance level.

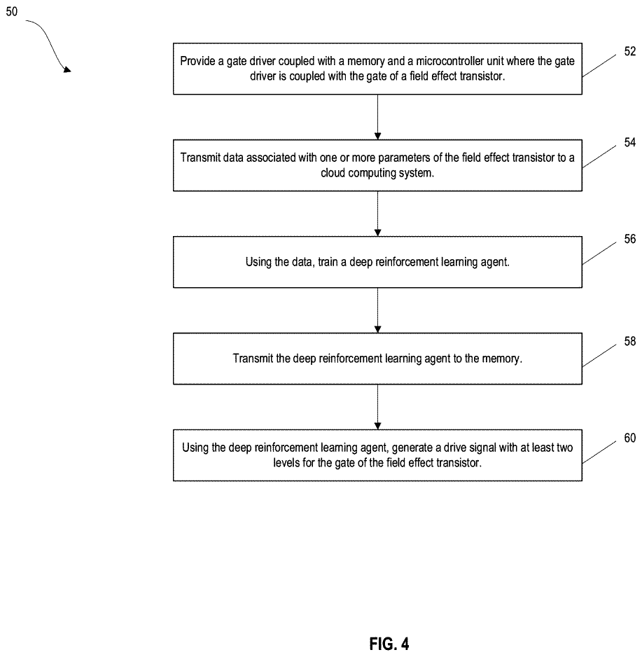

Referring to FIG. 4, the various gate driver systems disclosed herein may utilize various implementations of a method of training a deep reinforcement learning agent used during operation of a field effect transistor 50. The method includes providing a gate driver coupled with a memory and microcontroller unit (MCU) where the gate driver is coupled with the gate of a field effect transistor (step 52). The gate driver may be any disclosed in this document and the field effect transistor may be a silicon carbide FET like any disclosed herein. The memory and MCU may also be any disclosed in this document. The method includes transmitting data associated with one or more parameters of the field effect transistor to a cloud computing system (step 54). As previously discussed, the cloud computing system may be a centralized computing resource 38 available over a telecommunication channel. However, in some implementations, the centralized computing resource 38 may be available via a direct connection to the gate driver as it may be coupled with the same piece of equipment in which the gate driver is included (as in the case of an edge-located artificial intelligence computing system used to train the neural network or other model in the neural network system like those marketed under the tradename JETSON by NVIDIA of Santa Clara, California).

The method further includes using the data to train a deep reinforcement learning agent (step 56). As has been previously mentioned, the deep reinforcement learning agent can be implemented in the gate driver in several ways, some of which may depend on where the agent is trained. In a particular implementation, the deep reinforcement learning agent can be trained only with the cloud computing system 38 and then the as-trained agent transmitted across the telecommunication channel to the neural network system 18 and stored in the memory associated with the gate driver 10 for use and execution. In another implementation, the deep reinforcement learning agent can be trained at least partially on/with the gate driver 10 itself using, by non-limiting example, the MCU 16 in combination with the cloud computing system 38. In such an implementation, the cloud computing system 38 performs some training tasks while the MCU 16 performs other tasks either under the direction of the cloud computing system 38 or vice versa. In yet other implementations, the training takes place only on the gate driver 10 itself using the MCU 16. In such implementations, an initial general pre-trained model generated by the cloud computing system 38 may be provided to the gate driver 10 which the MCU 16 then works on evaluating, improving, and updating using its more limited computing resources.

The method further includes transmitting the now-trained deep reinforcement learning agent to the memory of the gate driver 10 (step 58). In some implementations this transmission may occur once, or may occur multiple times in response to training updates of the agent that take place periodically either on a regularly scheduled basis, an ad hoc basis, or after a certain event has occurred, such as, by non-limiting example, an out of SOA operating event, or the passage of a certain number of operating hours/cycles, or another triggering event. The particular deep reinforcement learning agent may be any agent type disclosed in this document. The method also includes using the deep reinforcement learning agent to generate a drive signal with at least two levels for the gate of the field effect transistor (step 60). This may take place as previously described in this document.

While the foregoing gate driver implementation 10 of FIG. 2 is illustrated and described herein, a wide variety of other gate driver implementations that may include one, all, or any of the various functions, structures, and capabilities described in this document. Many different model configurations, training configurations, and neural network/artificial intelligence modules/models may be constructed using the principles disclosed in this document.

The gate driver implementation 10 of FIG. 2 includes a number of other capabilities and functions one, all, or any of which may be included in other gate driver implementations. As illustrated in FIG. 2, the gate driver 10 includes a serial peripheral interface (SPI) for parameter configuration and communication with a microcontroller unit (MCU) included in the gate driver. In this implementation, 15 amp-pk driving current strength adjustment using the SPI in split output operation is possible, though higher or lower driving currents may be utilized in various other implementations. The gate driver is capable of integrated negative bias gate driving which is programmable to avoid turn on of the silicon carbide transistor when the drain voltage is up. In this implementation 1ry and 2ry active short circuit support is included that forces the state of the silicon carbide transistor (field effect transistor [FET] in this case) to allow for driving of the gate directly in case the MCU is not available to generate the generating signal. The gate driver also includes shoot through prevention with dead time which is programmable. As illustrated in FIG. 2, a 4.5 amp active Miller clamp (integrated) is included the gate driver which is compatible with an external active Miller clamp FET which is programmable. The use of the active Miller clamp is designed to activate a strong current pull down circuit when a VGS threshold is reached. The gate driver also utilizes desaturation (DESAT) sense control which is programmable to limit power dissipation when the silicon carbide transistor VDS is detected as being too high.

An over voltage clamp (OVC) is included to help prevent drain overvoltage of the silicon carbide transistor which can help reduce reliability issues for the silicon carbide transistor. The gate driver also includes a programmable soft turn off during detected fault conditions that involve potentially high current drain from the silicon carbide transistor. In this particular implementation, the gate driver also includes programmable undervoltage lock out (UVLO) at 4 volts and overvoltage lock out (OVLO) at 32 volts for VDD, VCC, and VEE. The gate driver also includes the capability to carry out direct current (DC) capacitance discharge. The various analog to digital converters (ADCs) in this gate driver implementation are integrated in the device and generate output at 10 bits. Temperature sensing capability for the silicon carbide transistor is also included in the gate driver implementation along with voltage sensing for direct current links, VCC, and others. The gate driver also includes various internal diagnostics including built in self-test (BIST) comparators and gate output stage monitoring in real time to alert quickly on detection of a fault condition. The gate driver also includes the capability to output information regarding detected faults/fault conditions with the silicon carbide transistor and/or gate driver itself.

In places where the description above refers to particular implementations of gate driver systems and related methods and implementing components, sub-components, methods and sub-methods, it should be readily apparent that a number of modifications may be made without departing from the spirit thereof and that these implementations, implementing components, sub-components, methods and sub-methods may be applied to other gate driver systems and related methods.

What is claimed is:

1. A system configured for operation of a field effect transistor, the system comprising:
a gate driver coupled with a memory and a microcontroller unit and a plurality of analog to digital converters, the gate driver configured to be coupled with a gate of a field effect transistor;
wherein the gate driver is configured to generate a drive signal with at least two levels for the gate of the field effect transistor, the drive signal with at least two levels generated using a deep reinforcement learning agent and data associated with one or more parameters of the field effect transistor.

2. The system of claim 1, wherein the gate driver is configured to be coupled with a telecommunication network and wherein the telecommunication network is configured to be operatively coupled with a cloud computing system which comprises the deep reinforcement learning agent and uses the deep reinforcement learning agent and the data associated with the one or more parameters of the field effect transistor to train the deep reinforcement learning agent and then transmit the deep reinforcement learning agent across the telecommunication network to the gate driver for storing in the memory.

3. The system of claim 1, wherein the deep reinforcement learning agent is comprised in the memory and the gate driver is configured to use the deep reinforcement learning agent and the data associated with one or more parameters of the field effect transistor to generate the drive signal.

4. The system of claim 1, wherein the deep reinforcement learning agent is comprised in the memory and is configured to communicate with a cloud computing system over a telecommunication network coupled with the gate driver where the cloud computing system is configured to use the data associated with one or more parameters of the field effect transistor to train the deep reinforcement learning agent to generate the drive signal with at least two levels associated with an operating area for the field effect transistor.

5. The system of claim 1, wherein the deep reinforcement learning agent is one of a deep Q-network, a double deep Q-network, an Actor-Critic agent, a policy gradient agent, a Monte Carlo tree search agent, an imitation learning agent, or any combination thereof.

6. The system of claim 1, wherein the deep reinforcement learning agent is trained using a deep neural network and a Markov decision process.

7. A system configured for operation of a field effect transistor, the system comprising:
a first gate driver and a second gate driver, the first gate driver and the second gate driver each coupled with a memory and a corresponding plurality of analog to digital converters, the first gate driver configured to be coupled with a gate of a first field effect transistor and the second gate driver configured to be coupled with a gate of a second field effect transistor;
wherein the first gate driver is configured to generate a first drive signal with at least two levels for the gate of the first field effect transistor, the first drive signal with at least two levels generated using a first deep reinforcement learning agent and data associated with one or more parameters of the first field effect transistor; and
wherein the second gate driver is configured to generate a second drive signal with at least two levels for the gate of the second field effect transistor, the second drive signal with at least two levels generated using a second deep reinforcement learning agent and data associated with one or more parameters of the second field effect transistor.

8. The system of claim 7, wherein the first deep reinforcement learning agent and the second deep reinforcement learning agent are the same deep reinforcement learning agent.

9. The system of claim 7, wherein each of the first gate driver and the second gate driver is configured to be coupled with a telecommunication network and wherein the telecommunication network is configured to be operatively coupled with a cloud computing system which comprises the first deep reinforcement learning agent and second deep reinforcement agent and wherein the cloud computing system:
uses the first deep reinforcement learning agent and the data associated with the one or more parameters of the first field effect transistor to train the first deep reinforcement learning agent and then transmits the first deep reinforcement learning agent across the telecommunication network to the first gate driver for storing in the memory; and
uses the second deep reinforcement learning agent and the data associated with the one or more parameters of the second field effect transistor to train the second deep reinforcement learning agent and then transmits the second deep reinforcement learning agent across the telecommunication network to the second gate driver for storing in the memory.

10. The system of claim 7, wherein:
the first deep reinforcement learning agent is comprised in the memory and the first gate driver is configured to use the first deep reinforcement learning agent and the data associated with one or more parameters of the first field effect transistor to generate the first drive signal; and
the second deep reinforcement learning agent is comprised in the memory and the second gate driver is configured to use the second deep reinforcement learning agent and the data associated with one or more parameters of the second field effect transistor to generate the second drive signal.

11. The system of claim 7, wherein:
the first deep reinforcement learning agent is comprised in the memory and is configured to communicate with a cloud computing system over a telecommunication network coupled with the first gate driver where the cloud computing system is configured to use the data associated with one or more parameters of the first field effect transistor to train the first deep reinforcement agent to generate the first drive signal with at least two levels associated with an operating area for the first field effect transistor; and
the second deep reinforcement learning agent is comprised in the memory and is configured to communicate with a cloud computing system over a telecommunication network coupled with the second gate driver where the cloud computing system is configured to use the data associated with one or more parameters of the second field effect transistor to train the second deep reinforcement agent to generate the second drive signal with at least two levels associated with an operating area for the second field effect transistor.

12. The system of claim 7, wherein the first deep reinforcement learning agent or the second deep reinforcement learning agent is one of a deep Q-network, a double deep Q-network, an Actor-Critic agent, a policy gradient agent, a Monte Carlo tree search agent, an imitation learning agent, or any combination thereof.

13. The system of claim 7, wherein the first deep reinforcement learning agent or second deep reinforcement agent is trained using a deep neural network and a Markov decision process.

14. A method of training a deep reinforcement learning agent used during operation of a field effect transistor, the method comprising:
providing a gate driver coupled with a memory, a microcontroller unit, and a plurality of analog to digital converters, the gate driver coupled with a gate of a field effect transistor;
transmitting data from the plurality of analog to digital converters associated with one or more parameters of the field effect transistor to a cloud computing system;
using the data, training a deep reinforcement learning agent;
transmitting the deep reinforcement learning agent to the memory; and
using the deep reinforcement learning agent, generating a drive signal with at least two levels for the gate of the field effect transistor.

15. The method of claim 14, wherein training the deep reinforcement learning agent includes training at least partially on the gate driver itself using the microcontroller unit.

16. The method of claim 14, wherein training the deep reinforcement learning agent includes training only with the cloud computing system.

17. The method of claim 14, wherein training the deep reinforcement learning agent includes training only on the gate driver itself using the microcontroller unit.

18. The method of claim 14, wherein the deep reinforcement learning agent is one of a deep Q-network, a double deep Q-network, an Actor-Critic agent, a policy gradient agent, a Monte Carlo tree search agent, an imitation learning agent, or any combination thereof.

19. The method of claim 14, wherein training the deep reinforcement learning agent further comprises training using a deep neural network and a Markov decision process.

20. The method of claim 14, wherein training the deep reinforcement learning agent further comprises where training defines an operating area for the field effect transistor.
